(19) United States
(12) Patent Application Publication
(10) Pub. No.: US 2018/0348434 A1
(43) Pub. Date: Dec. 6, 2018

(54) PHOTONIC DIE PACKAGE WITH EDGE LENS

(71) Applicant: Intel Corporation, Santa Clara, CA (US)

(72) Inventors: Myung Jin Yim, San Jose, CA (US); Sang Yup Kim, Sunnyvale, CA (US); Woosung Kim, Mountain View, CA (US)

(21) Appl. No.: 15/609,403

(22) Filed: May 31, 2017

(51) Int. Cl. G02B 6/26; H01L 31/0232; H01L 25/16; H01L 23/00; H01L 23/367; G02B 6/34

(52) U.S. Cl. CPC G02B 6/262; H01L 2924/12043; H01L 25/167; H01L 31/02325; H01L 24/17; H01L 24/81; H01L 23/3675; H01L 24/73; H01L 24/32; H01L 24/97; G02B 6/34; H01L 2924/1432; H01L 2224/16225; H01L 2224/73204; H01L 2224/73253; H01L 2224/32245; H01L 2924/1433; H01L 2224/13111; H01L 2224/13116; H01L 2224/13139; H01L 2224/13147; H01L 2224/2929; H01L 2224/29387; H01L 2924/0665; H01L 2924/05442; H01L 2224/32225; H01L 31/02327

(57) ABSTRACT

Embodiments herein may include apparatuses, systems, and processes related to a photonic die package with an edge lens that includes a photonic integrated circuit (IC) die, a lens coupled to the photonic IC die and disposed at an edge of the package to provide an optical path at the edge of the package for photon signals generated or received by the photonic IC die, and an electronic IC die coupled to the photonic IC die, where the electronic IC die is to process electrical signals received from the photonic IC die, and where the electronic IC die and the photonic IC die are in a stack formation to facilitate thermal energy conduction from the electronic IC die to the photonic IC die. Other embodiments may be described and/or claimed.

### FIELD

Embodiments of the present disclosure generally relate to the field of package assemblies, and in particular package assemblies having a lens coupled to a photonic integrated circuit (IC).

### BACKGROUND

The background description provided herein is for the purpose of generally presenting the context of the disclosure. Unless otherwise indicated herein, the materials described in this section are not prior art to the claims in this application and are not admitted to be prior art by inclusion in this section.

The increase of connected technologies and growth of Big Data are making ever bigger demands on data bandwidth and transmission speeds. Data centers are starting to look at using photons instead of electrons to send data faster between servers, racks, and boards, and also how to make high speed photonic connections between chips. Legacy implementations have included integration of photonics on silicon and integration of chips on interposers for standard IC packaging.

### BRIEF DESCRIPTION OF THE DRAWINGS

FIGS. 1A-1K illustrate an example of a package assembly that includes a photonic IC with a vertical inverted taper (VIT) coupling structure at various stages of a manufacturing process, in accordance with embodiments.

FIGS. 2A-2K illustrate an example of a package assembly that includes a photonic IC with an edge inverted taper (EIT) coupling structure at various stages of a manufacturing process, in accordance with embodiments.

FIG. 3 illustrates an example flow diagram showing a process 300 for manufacturing a package assembly that includes a photonic IC with an EIT coupling structure or a VIT, in accordance with embodiments.

FIGS. 4A-4G illustrate an example of an in-package photonics co-packaging assembly on a substrate at various stages of a manufacturing process, in accordance with embodiments.

FIG. 5 illustrates an example flow diagram showing a process 500 for manufacturing an in-package photonics co-packaging assembly on a substrate, in accordance with embodiments.

FIG. 6 schematically illustrates a computing device, in accordance with embodiments.

### DETAILED DESCRIPTION

Embodiments of the present disclosure generally relate to a photonic die package with an edge lens. In embodiments, the package may include a photonic IC die with a lens coupled to the photonic IC die and disposed at an edge of the package to provide an optical path at the edge of the package for photon signals generated or received by the photonic IC die. An electronic IC die may be coupled to the photonic IC die where the electronic IC die is to process electrical signals received from the photonic IC die. The electronic IC die and the photonic IC die may be in a stack formation to facilitate thermal energy conduction from the electronic IC die to the photonic IC die.

Legacy component ICs have focused on a single System-on-Chip (SoC) approach. In embodiments, optics ICs, both transmit (Tx) and receive (Rx), are stacked for electrical interconnection. The single SoC approach may be referred to as a “universal IC (UIC)” IC that may include a modulator driver, transimpedance amplifier (TIA), limiting amplifier (LA), clock and data recovery (CDR), micro controller (μController), and the like. Chip stacking between Tx, Rx, flash dice on UIC may be accomplished by micro-bumped face-to-face die bonding, and the system interconnect may be done by a three-dimensional (3D) through-silicon via (TSV) platform on backside bump of the UIC. In embodiments described herein, the photonic engine block approach may provide a flexible platform to support various optical module form factors, for example, pluggable, embedded and optics co-package integration. In particular, the optics co-packaging integration may include each UIC based photonic engine assembled in same package for the host IC with each Tx/Rx coupling structure and fiber array.

By contrast, embodiments herein may include improved mechanical reliability, particularly for the optical coupling manufacturability per individual Tx/Rx coupling with consideration on thermal dissipation inside co-packaging structure. Also the assembly compatibility between multi-die flip chip ball grid array (BGA) and the optics module co-package assembly together with optics die attach and fiber array attach on coupling structure is not easily feasible. In embodiments, fewer assembly steps and better reliable structure for optics co-package integration may facilitate and may reduce the risk for implementing a UIC approach with TSV interconnect for electrical interconnect and fiber array assembly for Tx and Rx photonic die on top of the UIC stacked components for high throughput.

In embodiments, the photonic IC may be integrated on electronic IC by using a wafer level package structure for providing an effective thermal, electrical and optical coupling structure. In addition, these embodiments may be manufactured with a high assembly throughput and packaging level optic system integration for photonic in-package assembly. By using wafer level packaging infrastructure, the optical module itself may become a fully integrated photonic engine that may allow the optical (photonic) path and electrical path downward, and thermal path upward in the assembly. In embodiments, during manufacturing the co-packaging assembly process may be fully compatible with conventional multi-die flip chip BGA assembly process with a heat spreader, and further optics assembly afterward either by passive alignment or active alignment.

Embodiments may also include one or more process flows that may enable the integration of a UIC on a photonic IC via chip-on-wafer level packaging. These embodiments may make the photonic engine die integration and optical coupling structure by mold edge interface for in-package photonics assembly compatible with the electrical and optical assembly requirements for high-volume manufacturing. Embodiments may provide an in-package photonics co-package and assembly architecture by photonic engine integration with mold edge coupling structure, that may be combined with host IC such as central processing unit (CPU), graphical processing unit (GPU), application specific IC (ASIC) and field programmable gate array (FPGA).

In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or elements are in direct contact.

Various operations may be described as multiple discrete operations in turn, in a manner that is most helpful in understanding the claimed subject matter. However, the order of description should not be construed as to imply that these operations are necessarily order dependent.

As used herein, the term “module” may refer to, be part of, or include an ASIC, FPGA, an electronic circuit, a processor (shared, dedicated, or group) and/or memory (shared, dedicated, or group) that execute one or more software or firmware programs, a combinational logic circuit, and/or other suitable components that provide the described functionality.

Various figures herein may depict one or more layers of one or more package assemblies. The layers depicted herein are depicted as examples of relative positions of the layers of the different package assemblies. The layers are depicted for the purposes of explanation, and are not drawn to scale. Therefore, comparative sizes of layers should not be assumed from the Figures, and sizes, thicknesses, or dimensions may be assumed for some embodiments only where specifically indicated or discussed.

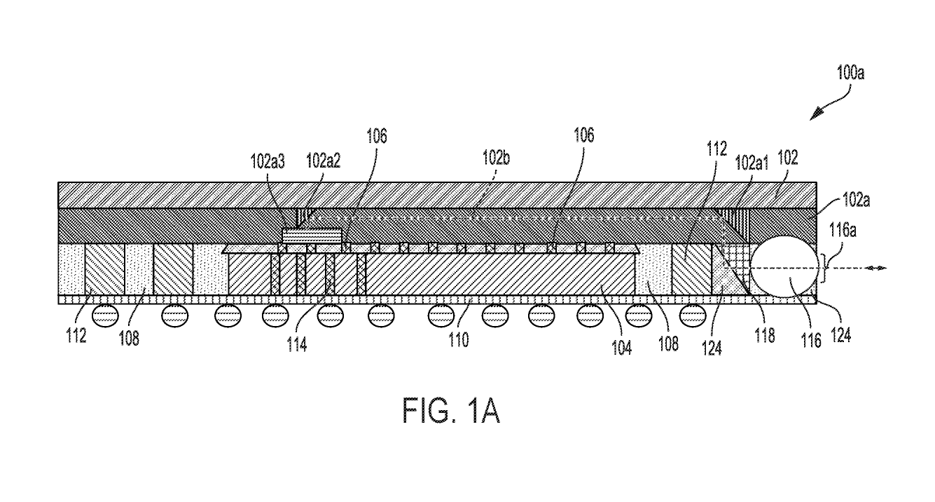

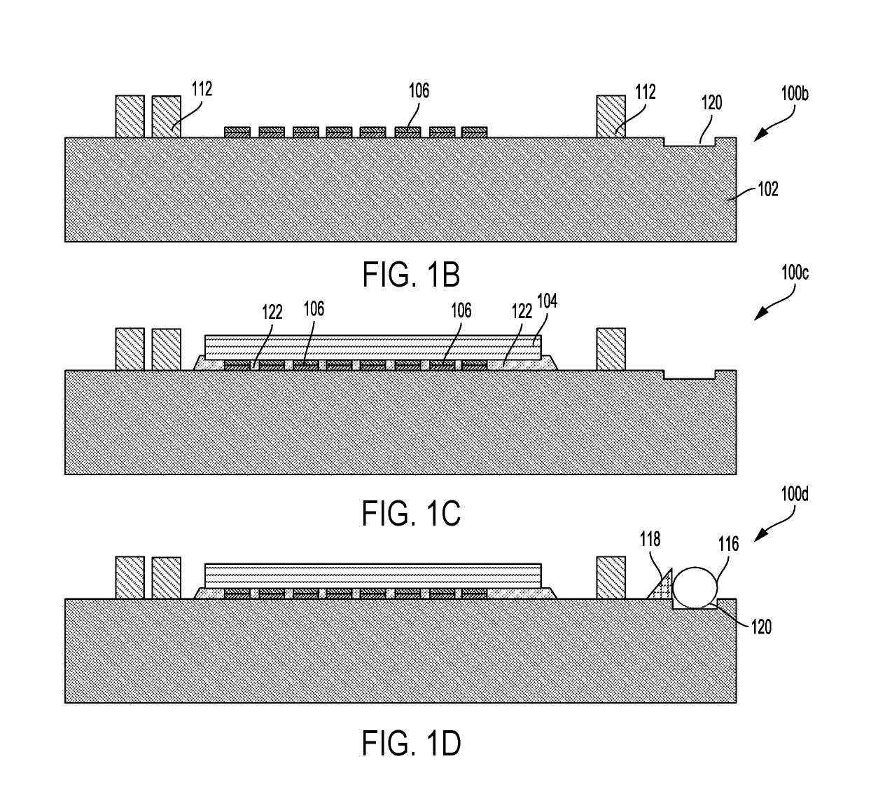

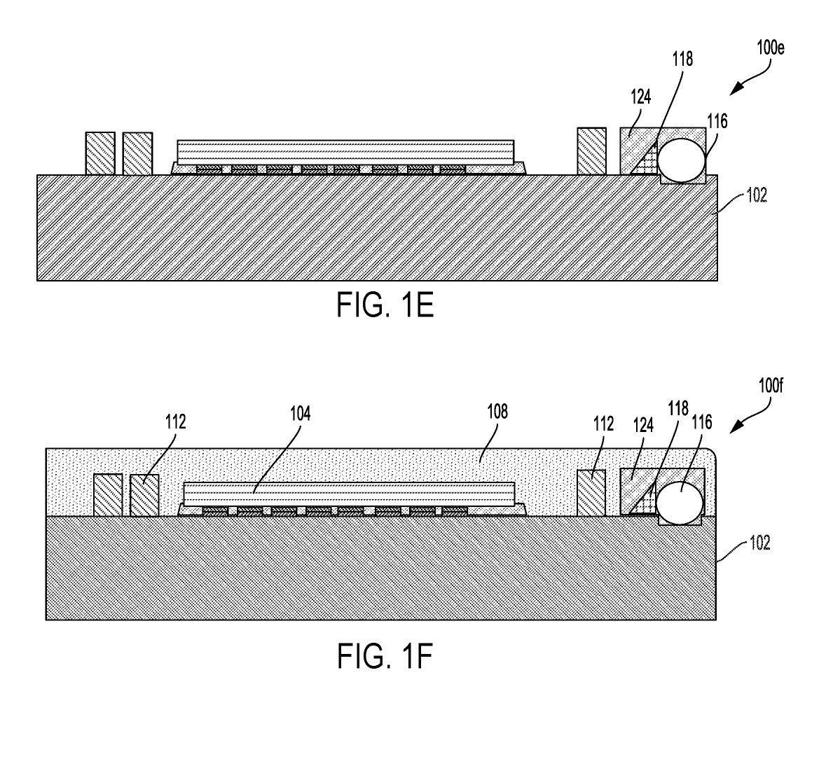

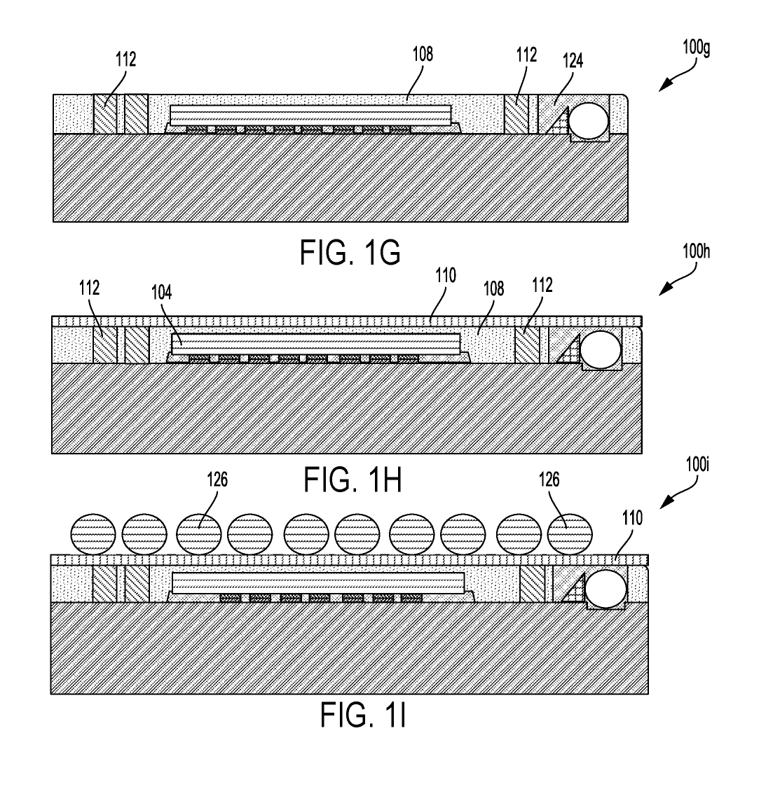

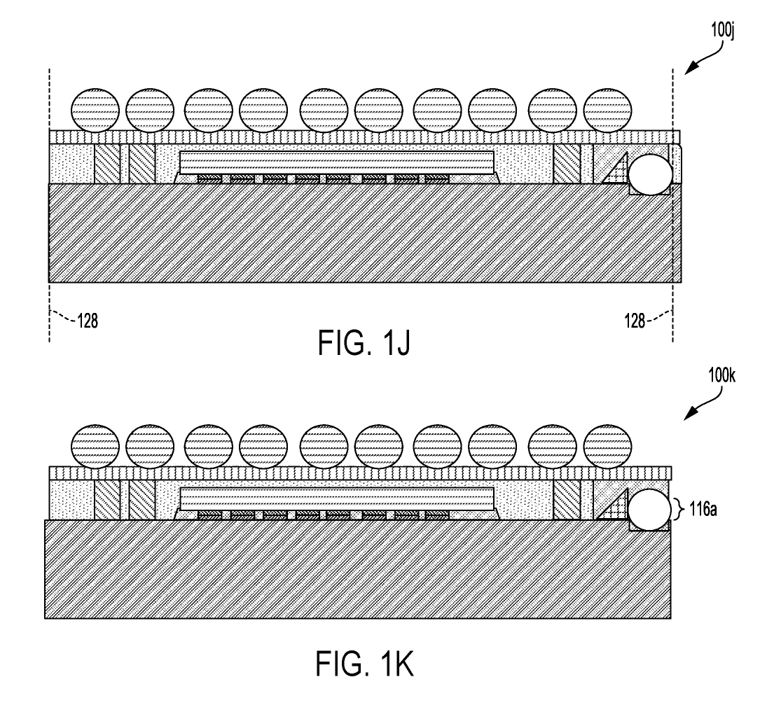

FIGS. 1A-1K illustrate an example of a package assembly that includes a photonic IC with a VIT coupling structure at various stages of a manufacturing process, in accordance with embodiments.

FIG. 1A shows a completed package assembly embodiment 100a that includes various stages of assembly. Package assembly 100a may include a photonic IC die 102 that may be part of a photonic IC wafer, which may be coupled to an electronic IC die 104 using bumps 106. In embodiments, the bumps 106 may be micro-bumps, which in embodiments may include micro-bumps with bump pitches ranging from 50-130 microns. The bumps 106 in embodiments may be metal solder bumps that may include tin, lead, silver, and/or copper in various combinations. In embodiments, the bumps 106 may be applied using a wafer bumping process for the photonic IC die 102. In embodiments, the photonic IC die 102 and the electronic IC die 104 may be assembled by face-to-face bonding; for example, active circuitry area of the photonic IC die 102 and the active circuitry area of the electronic IC die 104 may be bonded directly through the bump joint. In embodiments, the electronic IC die 104 may be a UIC. In embodiments, underfill 120, which may include epoxy-based resin filled with inorganic fillers such as silicon oxide to control thermo-mechanical properties, may be placed between the bumps 106 and the electronic IC die 104. In embodiments, the electronic IC die 104 may be partially embedded in a molding compound 108. In embodiments, the molding compound 108 may be an epoxy molding compound. In embodiments, the electronic IC die 104 may be coupled to a redistribution layer (RDL) 110.

In embodiments, the photonic IC die 102 may be coupled with the RDL 110 using connectors 112. The connectors 112 may be copper posts that may be created as tall copper columns that are plated at a height. In embodiments, the electronic IC die 104 may include one or more through silicon vias (TSVs) 114. In embodiments, the photonic IC die 102 may also include integrated Tx/Rx capabilities (not shown for readability).

A ball lens 116, which in examples may be approximately 0.3 to 10 mm in diameter and may be made from typical glass material, for example borosilicate glass Schott BK7 (BK7), may be disposed substantially within the molding 108, and coupled to a prism 118. In embodiments, the ball lens 116 and the prism 118 may be coupled by being encased in an optical epoxy molding 124. In embodiments, the optical epoxy molding 124 may be an optically clear composition that may include epoxies, urethanes, silicones, cyanoacrylates and/or polyester resin-based materials.

In embodiments, the prism 118 may be approximately 0.1 millimeter (mm) to 1mm length and width and may be made from BK7. A portion of the ball lens surface 116a may facilitate receiving and transmitting photons to and from outside the package 100a via the prism 118 to the photonic IC 102.

In embodiments, the photonic IC die 102 may include a layer 102a that may include a VIT coupling structure. The VIT coupling structure may be used to receive photons from a direction perpendicular to the plane of the photonic IC die 102 and reorient them in a direction parallel to the plane of the photonic IC die 102. The VIT coupling structure may include a first on-chip prism 102a1. In embodiments, when the photonic IC die 102 is in receive (Rx) mode, a re-entrance mirror photo detector (REMPD) array coupling structure may include a first on-chip prism 102a1, a second on-chip prism 102a2, and a photodiode 102a3.

In embodiments, when the photonic IC die 102 is in Rx mode, the path of light 102b may enter a surface of the ball lens 116a, pass through the ball lens 116, be reflected 90° by a prism 118 to the first on-chip prism 102a1, then proceed to the second on-chip prism 102a2, then be reflected 90° to the photodiode 102a3. In embodiments, inside of the ball lens 116, the rays of light may become collimated.

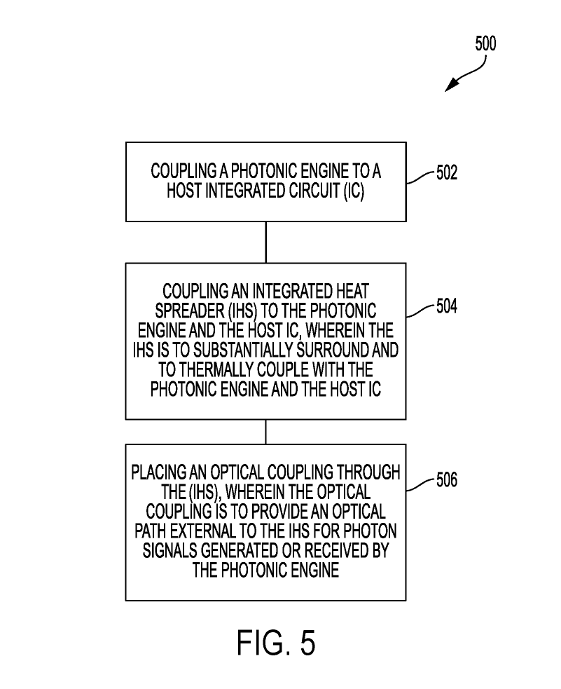

In embodiments, when the photonic IC die 102 is in transmit (Tx) mode, the path of light 102b may originate at a laser embedded on the photonic IC 102 (not shown), be reflected 90° by the first on-chip prism 102a1, be reflected 90° to the prism 118, then be reflected 90° through the ball lens 116 and out the ball lens opening 116a. In embodiments, when the light exits from ball lens 116, it may get diffracted and focused onto a fiber facet (not shown). At this point, the package 100a may be a fully integrated photonic engine die that may be prepared to be assembled on a host IC package as discussed further below with respect to FIG. 5. In embodiments, the package 100a, when in operation, may be generally characterized as having electrical flow downward, optical path flow edge-ward and thermal path flow upward with respect to the orientation of FIG. 1A. Note: the layer 102a is shown only in FIG. 1A for the sake of clarity of the other figures.

FIG. 1B shows an initial package assembly embodiment 100b that may include a photonic IC die 102, which may be similar to the photonic IC die 102 of FIG. 1A. The photonic IC wafer 102a may include one or more bumps 106, and may include one or more connectors 112. In embodiments, the bumps 106 and connectors 112 may be applied as dual-height bumps. In embodiments, dual-height bumps may be formed with different height and/or different diameters. The connectors 112 may be plated to be tall copper columns.

A trench 120 may be created in the photonic IC die 102. The trench 120 may be used to facilitate placement and/or securing of the ball lens 116 of FIG. 1A in the photonic IC die 102 of FIG. 1A. The trench 120 may be shallow so that a greater portion of the ball lens 116 will be outside the photonic IC die 102 when the ball lens 116 is placed in the trench 120. In embodiments, to form the trench 120, a potassium hydroxide (KOH) wet etch process may be used. In embodiments, this process can create a recess based on a silicon crystalline structure. The etched recess may be a square shape with fixed angle, for example 45 degree or 55 degree, that, for example, may depend on an orientation of a lithography mask.

Next, as shown in FIG. 1C, in embodiment 100c an electronic die 104 may be placed on the bumps 106. In embodiments, this may be done with a mass reflow process, a thermo-compression bonding process, or some other process. In addition, an underfill 122 may be placed between the bumps 106 and/or between the electronic IC die 104 and the photonic IC die 102.

Next, as shown in FIG. 1D, in embodiment 100d the ball lens 116 may be placed in the trench 120. In addition, the prism 118 may be placed adjacent to or in close proximity to the ball lens 116. In embodiments, the prism 118 may be to direct photons into and out of the photonic IC die 102.

Next, as shown in FIG. 1E, in embodiment 100e optical epoxy molding 124 is applied to the ball lens 116 and prism 118. The optical epoxy molding 124 may encapsulate the ball lens 116 and prism 118, and may also encapsulate the trench 120 of FIG. 1A and portions of the photonic IC wafer 102. The optical epoxy molding 124 may be limited to fill the prism 118 and ball lens 116 area on top of the photonic IC wafer 102. In embodiments, a localized wafer-level molding process may be used to apply the optical epoxy molding 124. The optical epoxy molding 124 may be to protect the optical path of the light within the package 100e.

Next, as shown in FIG. 1F, in embodiment 100f a molding compound 108 may be applied. In embodiments, the molding compound 108 may be applied using a wafer level epoxy molding process to fill all empty areas on the photonic IC wafer 102. The molding compound 108 may encapsulate the connectors 112, the electronic IC die 104, and the optical epoxy molding 124 that encapsulates the ball lens 116 and prism 118.

Next, as shown in FIG. 1G, in embodiment 100g a grinding process may be applied to grind the molding compound 108 down to expose a top portion of the connectors 112, the optical epoxy molding 124 and/or other components (not shown). In embodiments, this may expose the connectors 112 and/or other components (not shown) for electrical coupling.

Next, as shown in FIG. 1H, in embodiment 100h a RDL 110 may be applied to the top of the ground molding 108. In embodiments, the RDL 110 may be a backside RDL. In embodiments, the backside RDL may be formed by dielectric layer deposition such as polyimide and patterning with metal conductor such as copper layer to route electrical signal and power between the connectors 112 and bump array 126 of FIG. 1I. In embodiments, the RDL 110 may be electrically coupled with the connectors 112. In embodiments, the RDL 110 may be adjacent or directly coupled (not shown) to the electronic IC die 104.

Next, as shown in FIG. 1I, in embodiment 100i a ball attach process may be applied to attach solder balls to create a bump array126 onto one or more metal pads (not shown) in the RDL 110. In embodiments, this may be done by ball placement and reflow process or electro-plating and reflow process.

Next, as shown in FIG. 1J, in embodiment 100j wafer-level dicing may occur at dicing points 128 as part of a singulation process. In embodiments, prior to wafer-level dicing, an intermediate wafer level test may be conducted (not shown) that may identify properly and improperly functioning dies.

Next, as shown in FIG. 1K, in embodiment 100k mold edge cleaning process may occur to expose the portion of the ball lens surface 116a. The mold edge cleaning process may clean mold or wafer-level molding residue after singulation. The cleaning process may facilitate receiving and transmitting photons at the edge of the package 100k.

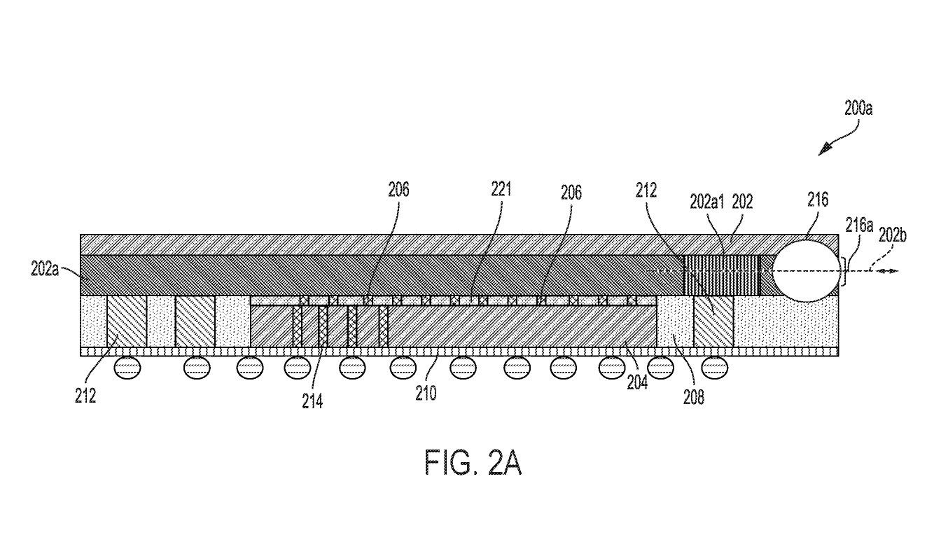

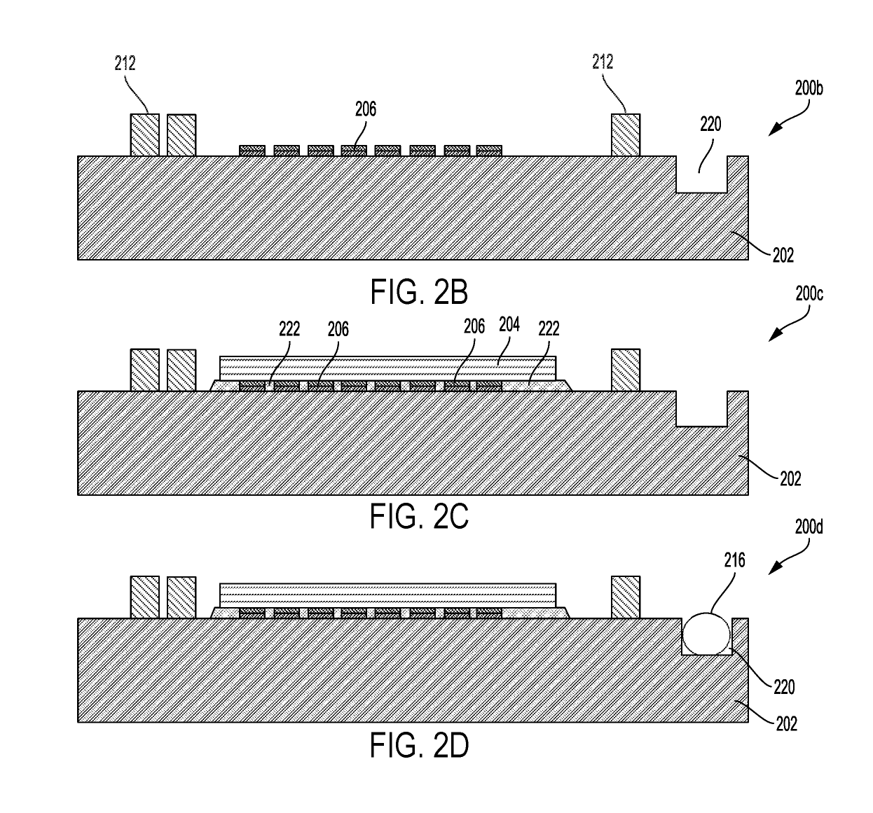

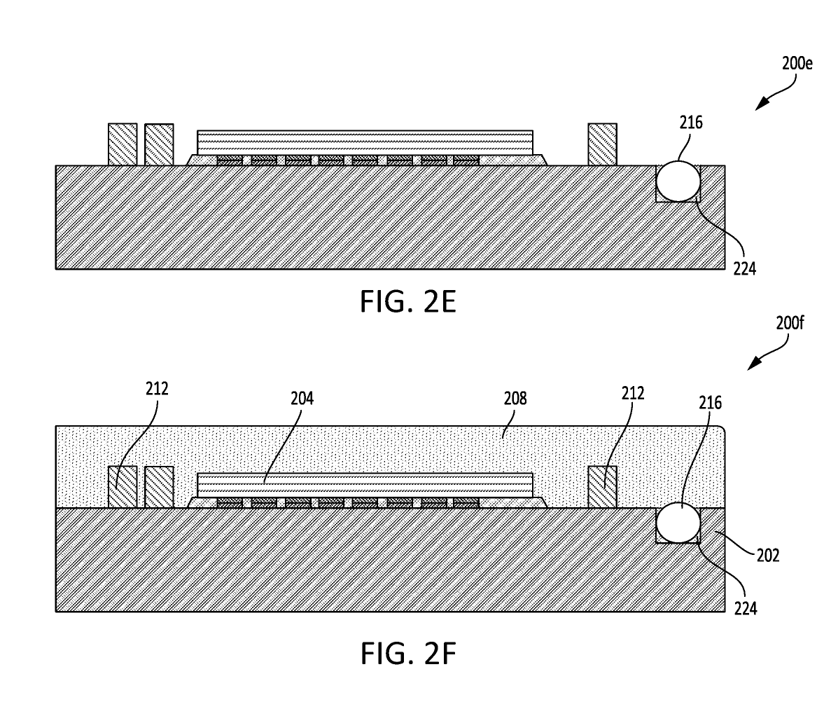

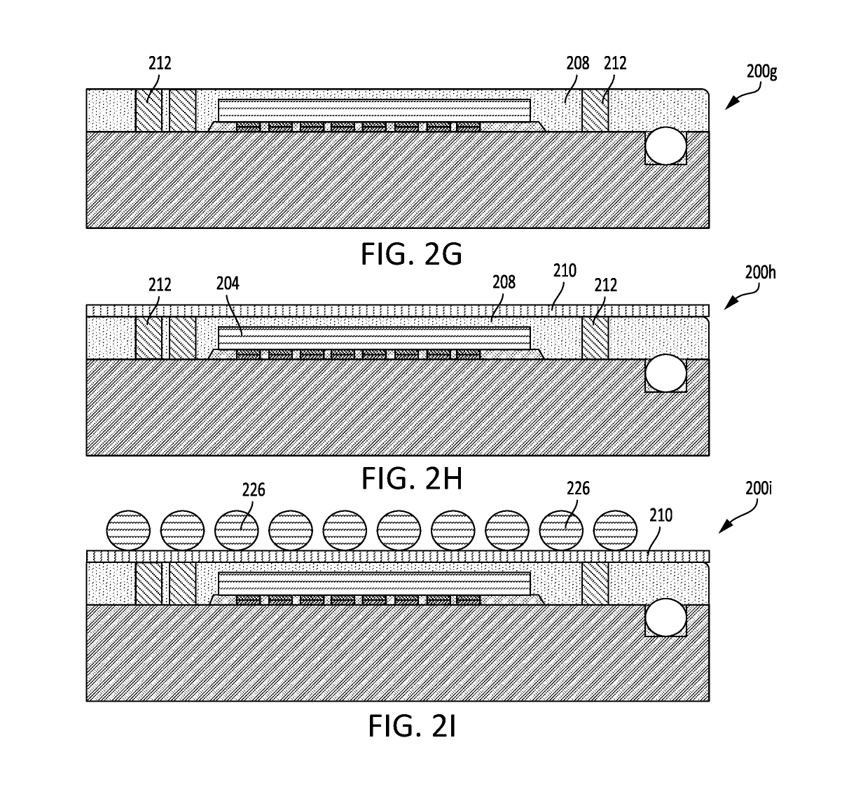

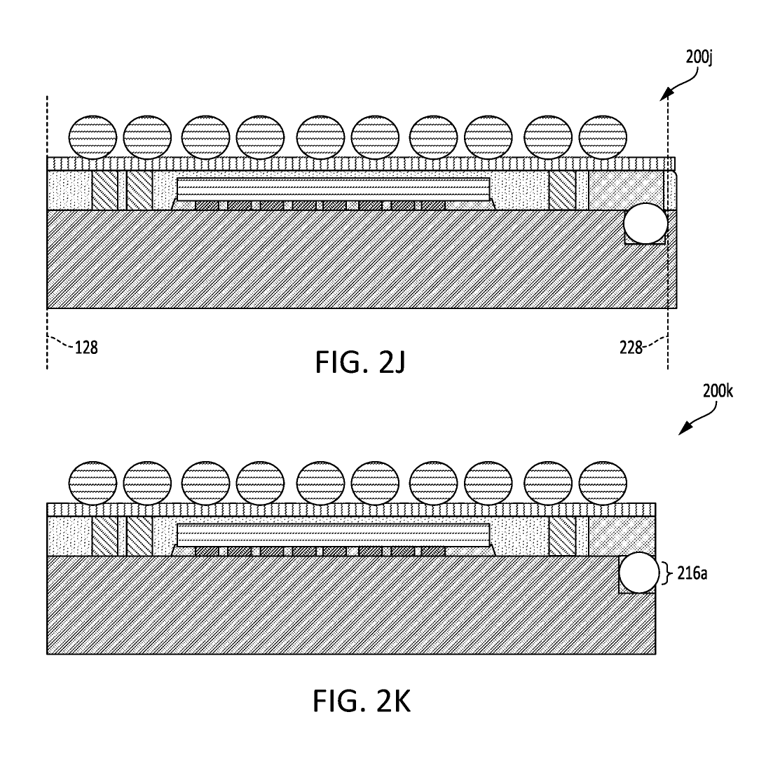

FIGS. 2A-2K illustrate an example of a package assembly that includes a photonic IC with an EIT coupling structure at various stages of a manufacturing process, in accordance with embodiments.

FIG. 2A shows a completed package assembly embodiment 200a that includes various stages of assembly. Package assembly 200a may include a photonic IC die 202, which may be similar to the photonic IC die 102 of FIG. 1A, that may be part of a photonic IC wafer, which may be coupled to an electronic IC die 204, which may be similar to the electronic IC die 104 of FIG. 1A, via bumps 206, which may be similar to the bumps 106 of FIG. 1A. The bumps 206 may be applied using a wafer bumping process for the photonic IC die 202. The photonic IC die 202 and the electronic IC die 204 may then be assembled by face-to-face bonding. In embodiments, the bumps 206 may be micro-bumps. In embodiments, the electronic IC die 204 may be an electronic UIC. In embodiments, underfill 221 may be placed between the bumps 206 and the electronic IC die 204. In embodiments, the electronic IC die 204 may be partially embedded in a molding compound 208, which may be similar to the molding compound 108 of FIG. 1A. In embodiments, the electronic IC 204 die may be coupled to an RDL 210, which may be similar to the RDL 110 of FIG. 1A.

In embodiments, the photonic IC die 202 may be coupled with the RDL 210 using connectors 212, which may be similar to the connectors 112 of FIG. 1A. The connectors 212 may be copper posts that may be created as tall copper columns that are plated at a height. In embodiments, the electronic IC die 204 may include one or more TSVs 214, which may be similar to the TSVs 114 of FIG. 1A.

The photonic IC die 202 may include an EIT layer 202a that includes an EIT 202a1. In embodiments, when the photonic IC die 202 is in Rx mode, the path of light 202b may enter a surface of the ball lens 216a, pass through the ball lens 216, through the EIT 202a1, for further processing within the EIT layer 202a. In embodiments, when the photonic IC die 202 is in Tx mode, the path of light 202b may originate within the EIT layer 202a, pass through the EIT 202a1, through the ball lens 216 and out the surface of the ball lens 216a. The EIT may be used to receive photons from a direction parallel to the plane of the photonic IC die 202 and to facilitate sending those photons further into the photonic IC die 102.

A ball lens 216, which may be similar to the ball lens 116 of FIG. 1A, may be disposed substantially within the photonic IC die 202. A portion of the ball lens surface 216a, which may be similar to the ball lens surface 116a of FIG. 1A, may facilitate receiving and transmitting photons to and from outside the package 200a and the photonic IC 202. Note that this implementation differs from the implementation of 100a of FIG. 1A.

At this point, the package 200a may be a fully integrated photonic engine die that may be prepared to be assembled on a host IC package as discussed further below with respect to FIG. 5. Note: the EIT layer 202a is shown only in FIG. 2A for the sake of clarity in the other figures.

FIG. 2B shows an initial package assembly embodiment 200b that may include a photonic IC die 202. The photonic IC die 202 may include one or more bumps 206, and may include one or more connectors 212. In embodiments, the bumps 206 and connectors 212 may be applied as dual-height bumps. The connectors 212 may be plated to be tall copper columns.

A trench 220 may be created in the photonic IC die 202. In embodiments, the trench 220 may be similar to but deeper than the trench 120 of FIG. 1B, so that substantially all of the ball lens 216 may be disposed within the photonic IC die 202 when placed into the trench 220. In embodiments, the trench 220 may facilitate securing the ball lens 216 in the photonic IC wafer 202a. In embodiments, the trench 220 may be an EIT trench that may be a 90 degree facet created by dry etch and may hold the ball lens 216 for outcoupling to optical fiber (not shown).

Next, as shown in FIG. 2C, in embodiment 200c an electronic die 204 may be placed on the bumps 206. In addition, underfill 222, which may be similar to the underfill 122 of FIG. 1C, may be placed between the bumps 206 and/or between the electronic IC die 204 and the photonic IC die 202.

Next, as shown in FIG. 2D, in embodiment 200d the ball lens 216 may be placed in the trench 220. In embodiments, with the placement of the ball lens 216 into the trench 220 in the photonic IC die 202, a prism may not be required because light coupling may be directly horizontal to the ball lens 216. The depth of the trench 220 may cause most of ball lens 216 to be seated within the photonic IC die 202. Note that because light is emitted from the photonic chip horizontally, 90 degree reflection may not be required and thus a prism my not be needed to re-direct light to the photonic IC die 202. This may be different from the implementation shown in diagram 100d of FIG. 1D.

Next, as shown in FIG. 2E, in embodiment 200e optical epoxy molding 224, which may be similar to the optical epoxy molding 124 of FIG. 1E, may be applied to secure the ball lens 216 into the trench 220 of FIG. 2D. In embodiments, the optical epoxy molding 224 may be to protect the optical path from through ball lens 216 during the photonic engine wafer level integration process.

Next, as shown in FIG. 2F, in embodiment 200f a molding compound 208, which may be similar to the molding compound 108 of FIG. 1F, may be applied. In embodiments, the molding compound 208 may be applied using a wafer-level epoxy molding process to fill all empty areas on the photonic IC die 202. The molding compound 208 may encapsulate the connectors 212, the electronic IC die 204, the ball lens 216, and/or the optical epoxy molding 224 that secures and couples the ball lens 216 to the photonic IC die 202.

Next, as shown in FIG. 2G, in embodiment 200g, a grinding process may be applied to grind the molding compound 208 down to expose a top portion of the connectors 212 and/or other components (not shown). In embodiments, this may expose the connectors 212 and/or other components (not shown) for electrical coupling.

Next, as shown in FIG. 2H, in embodiment 200h an RDL 210, which may be similar to the RDL 110 of FIG. 1H, may be applied to the top of the ground molding 208. In embodiments, the RDL 210 may be a backside RDL. In embodiments, the RDL 210 may be electrically coupled with the connectors 212. In embodiments, the RDL 210 may be adjacent to or coupled with (not shown) the electronic IC die 204.

Next, as shown in FIG. 2I, in embodiment 200i a ball attach process may be applied to attach solder balls 226, which may be similar to the solder balls 126 of FIG. 1I, onto one or more metal pads (not shown) in the RDL 210.

Next, as shown in FIG. 2J, in embodiment 200j a wafer-level dicing may occur at dicing points 228, which may be similar to the dicing points 128 of FIG. 1J as part of a singulation process. In embodiments, prior to wafer-level dicing, an intermediate wafer level test may be conducted that may identify properly and improperly functioning dies.

Next, as shown in FIG. 2K, in embodiment 200k mold edge cleaning may occur to expose the portion of the ball lens surface 216a. The mold edge cleaning process may clean mold or wafer level molding residue after singulation. The cleaning process may facilitate receiving and transmitting photons at the edge of the package 200k at the ball lens surface 216a.

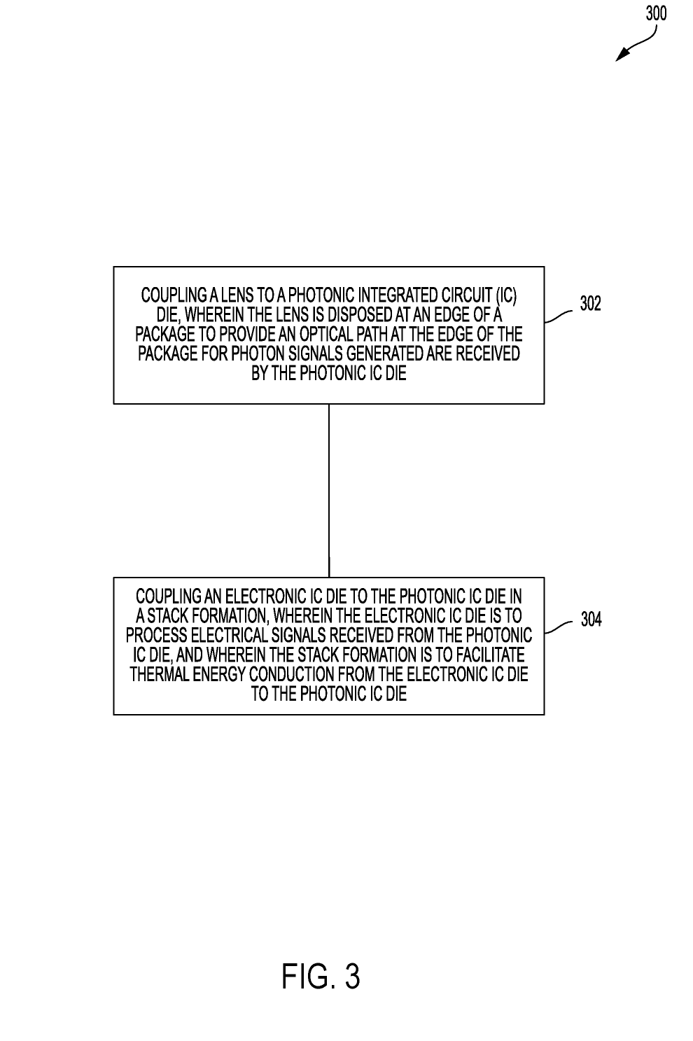

FIG. 3 illustrates an example flow diagram showing a process 300 for manufacturing a package assembly that includes a photonic IC with an EIT coupling structure or a VIT coupling structure, in accordance with embodiments.

At block 302, a lens may be coupled to a photonic IC die, wherein the lens is disposed at an edge of the package to provide an optical path at the edge of the package for photon signals generated or received by the photonic IC die. In embodiments, the individual actions of block 302 may be indicated by the actions referred to with respect to FIGS. 1D-1K or FIGS. 2D-2K. In embodiments, the lens, which may be similar to the lens 116, 216, may be coupled to a photonic IC die, which may be similar to the photonic IC die 102, 202. The lens may be disposed at the edge of the package, which may be similar to the package 110k, 210k, where the optical path for photon signals generated or received by the photonic IC die may be facilitated by the exposed portion of the lens, which may be similar to the exposed portions 116a, 216a of the lens 116, 216 at the edge of the package 110k, 210k.

At block 304, an electronic IC die may be coupled to the photonic IC die in a stack formation, wherein the electronic IC die is to process electrical signals received from the photonic IC die, and wherein the stack formation is to facilitate thermal energy conduction from the electronic IC die to the photonic IC die. In embodiments, the individual actions of block 304 may be indicated by the actions referred to with respect to FIGS. 1B-1C or FIGS. 2B-C. In embodiments, the photonic IC die may be similar to the photonic IC die 102, 202 of FIG. 1B, and the electronic IC die may be similar to the electronic IC die 104, 204. In embodiments, the dies may be connected by bumps 106, 206 and/or underfill 122, 222 to create a stacking structure that may be similar to that shown diagrams 100c or 200c.

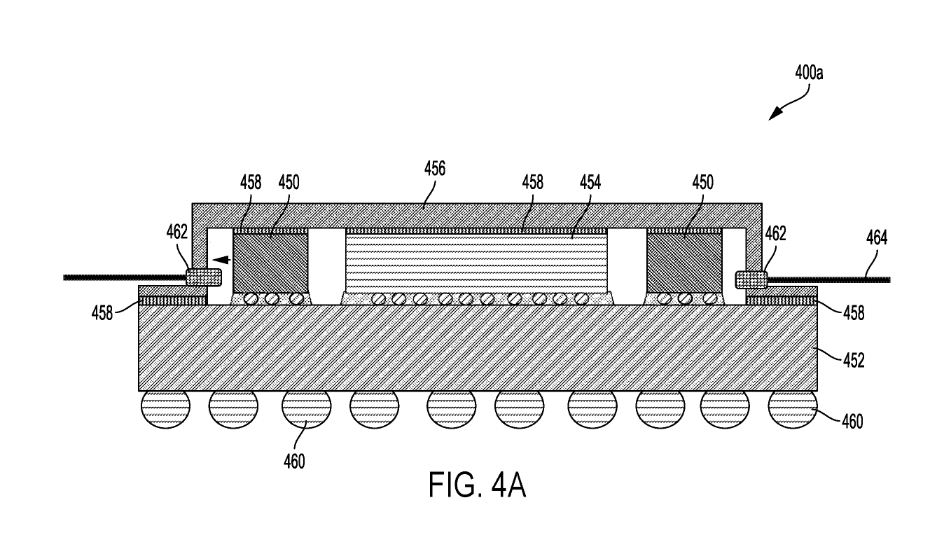

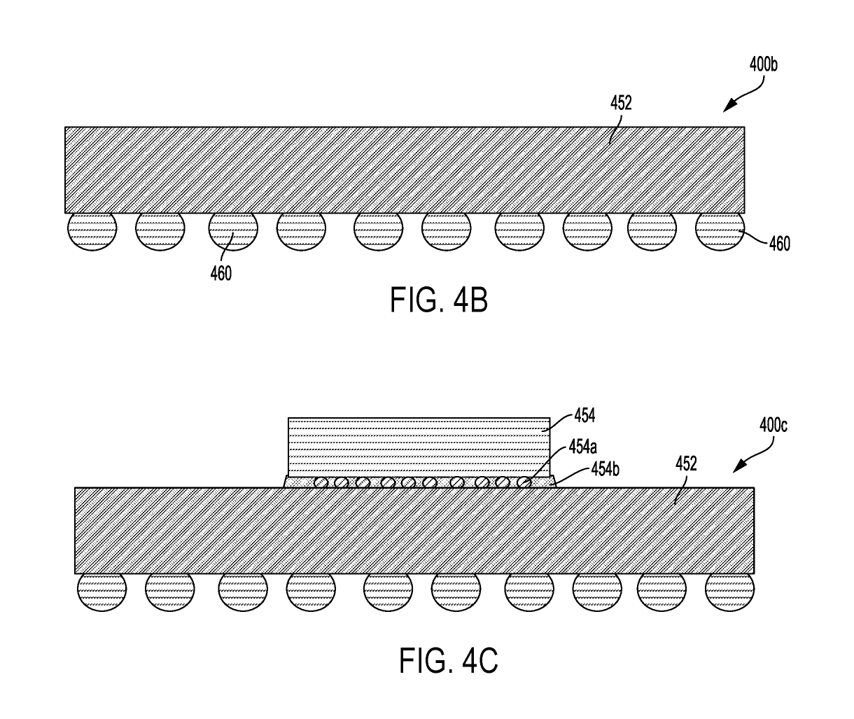

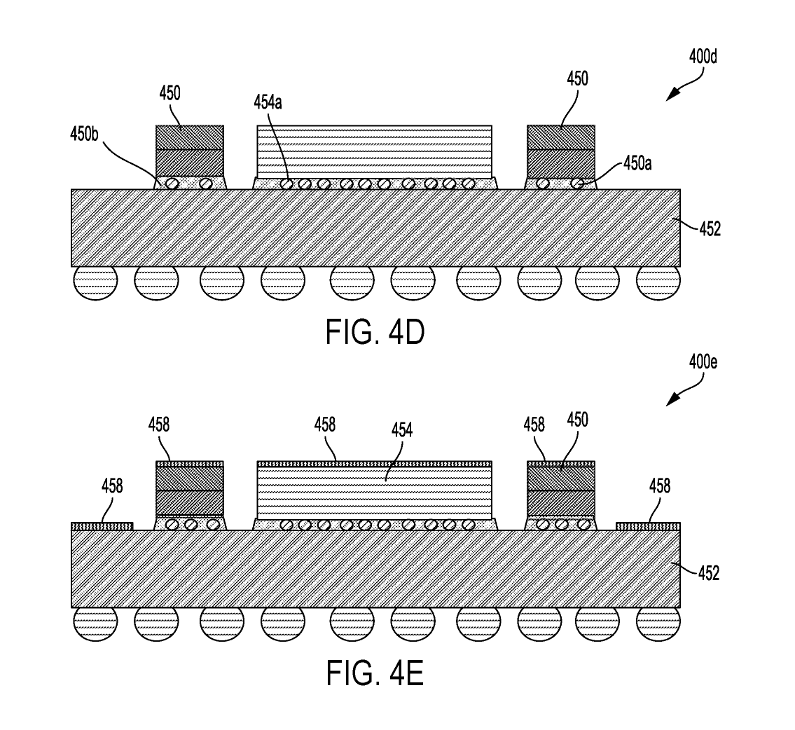

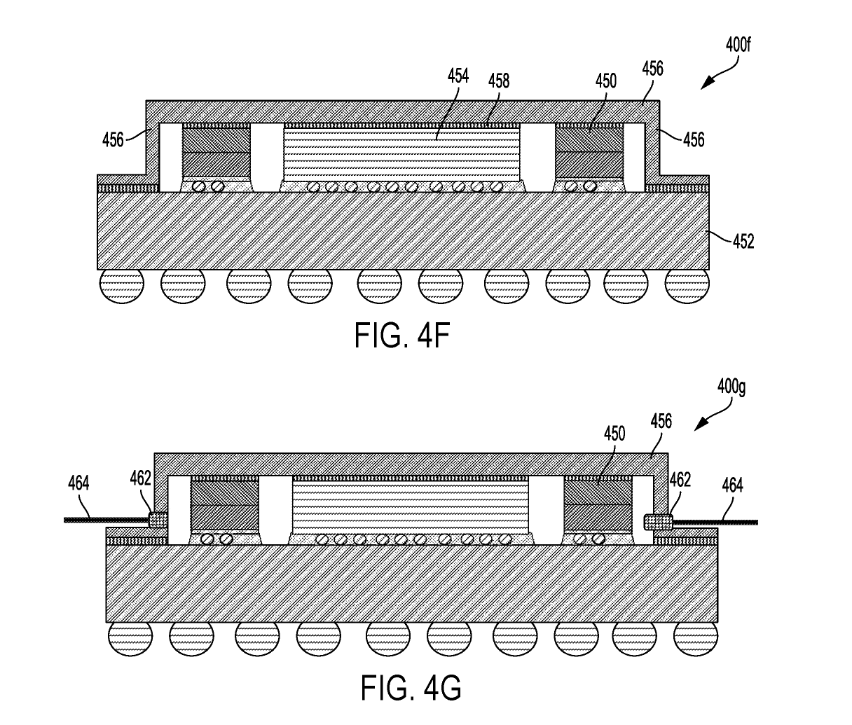

FIGS. 4A-4G illustrate an example of an in-package photonics co-packaging assembly on a substrate at various stages of a manufacturing process, in accordance with embodiments.

FIG. 4A shows a completed co-package assembly embodiment 400a that includes various stages of assembly. Package assembly 400a may include one or more photonic engines 450, which may be similar to the package 100a of FIG. 1A or the package 200a of FIG. 2A. The photonic engines 450 may be coupled to an IC package substrate 452. One or more other ICs 454 may be attached to the IC package substrate 452. In embodiments, the one or more other ICs 454 may include a host IC, a CPU, an ASIC, or some other appropriate IC such as a FPGA or a network switch. In embodiments, the top of the IC package substrate 452 may be prepared with electrical routing (not shown) to facilitate electrical coupling between the one or more other ICs 454, the photonic engines 450, and the IC package substrate 460.

The one or more photonic engines 450 and the one or more other ICs 454 may be thermally coupled with an IHS 456. In embodiments, the IHS 456 may include copper or a copper alloy, and may be nickel plated. In embodiments, the IHS 456 may partially surround or completely surround the one or more photonic engines 450 and the one or more other ICs 454. In embodiments, a thermal interface material (TIM) 458 may thermally couple the IC package substrate 452, the one or more photonic engines 450, and/or the one or more other ICs 454 to the IHS 456. In embodiments, the TIM 458 may include any material to enhance thermal coupling between two components, and may include thermal grease, thermal glue, thermal gap filler a thermal pad, a thermal adhesive, or some other appropriate thermal coupling material. In embodiments, the IC package substrate 452 may have one or more balls 460 of a ball grid array coupled to the bottom of the IC package substrate 452.

An optical coupling structure 462, which may be coupled to each photonic engine 450, may be coupled to a SMF array 464. In embodiments, the optical coupling structure 462 may pass through the IHS 456 and may be secured by using a soft epoxy. In embodiments, the optical coupling structures 462 may provide the only access ports to components within the IHS 456. The coupling between the optical coupling structure 462 and the photonic engine 450 may be performed by passive alignment or by active alignment. In embodiments, the optical coupling structure 462 may include an SMF ferrule (not shown) that may attach to an optical bench (not shown). In embodiments, a silicon optical bench (not shown), may be used to provide additional rigidity and increase tolerances.

In embodiments, assembly of the co-package 400a may be performed by standard multi-die chip attach processes.

FIG. 4B shows an initial co-package assembly embodiment 400b that may include an IC package substrate 452. In embodiments, the size of the IC package substrate 452 may range from 40 mm×40 mm to 70 mm×70 mm. In embodiments, the IC package substrate 452 may have 10 or more layers that may include an organic core layer and organic build up or copper layers. In embodiments, a top surface of the IC package substrate 452 may be used for chip assembly and a bottom surface may be used for connecting to a motherboard or system board. In embodiments, balls 460 of a ball grid array may be coupled to one side of the IC package substrate 452. In embodiments, a RDL (not shown) may be placed on the opposite side of the IC package substrate 452.

Next, as shown in FIG. 4C, in embodiment 400c a host IC 454 may be coupled to the IC package substrate 452. In embodiments, the host IC 454 may be coupled with an RDL (not shown) on the IC package substrate 452. An underfill 454b may be applied between the host IC 454 and the IC package substrate 452. In embodiments, the underfill 454b may surround the solder bumps 454a.

Next, as shown in FIG. 4D, in embodiment 400d, one or more photonic engines 450 may be coupled to the IC package substrate 452. In embodiments, the photonic engines 450 may be similar to the package assembly embodiment 100a of FIG. 1A, or 200a of FIG.2A. In embodiments, the photonic engine 450 may be coupled with the IC package substrate 452 using solder bumps 450a. In embodiments, an underfilling 450b may be applied between the photonic engine 450 and the IC package substrate 452. In embodiments, the underfilling 450b may surround the solder bumps 450a.

The one or more photonic engines 450 may have a transmit and receive ball lens array, similar to ball lens 116 of FIG. 1A or 216 of FIG.2A, that may be on the photonic engine 450 die mold edge.

Next, as shown in FIG. 4E, in embodiment 400e, a TIM 458 may be applied to a surface of IC package substrate 452, the one or more photonic engines 450, or the host IC 458. In embodiments, the TIM 458 may facilitate a thermal connection between the various components and the IHS 456 of FIG. 4F.

Next, as shown in FIG. 4F, in embodiment 400f, an IHS 456 may be applied and thermally coupled to the IC package substrate 452, the photonic engine 450, and/or the host IC 458. In embodiments, an IHS adhesive (not shown) may be dispensed on a peripheral area of the IC package substrate 452. In embodiments, the IHS 456 may also act as a stiffener for the substrate 452. In embodiments, the IHS 456 may be thermally coupled to the components by coming in contact with the TIM 458 applied to the components. In embodiments, the IHS 456 may partially surround or may completely surround the IC package substrate 452, the photonic engine 450, and/or the host IC 454. In embodiments, the IHS 456 may be a copper-based heat spreader with a nickel coating layer that may facilitate adhesion and may protect against copper oxidation.

Next, as shown in FIG. 4G, in embodiment 400g, optical couplings 462 may be added. In embodiments, one or more optical couplings 462 may pass through a wall of the IHS 456 to provide an optical/photonic connection between a SMF array 464 and a photonic engine 450. In embodiments, there may be one optical coupling 462 associated with each photonic engine 450. In embodiments, as described above, the optical coupling 462 may be secured by using a soft epoxy. Other embodiments may also include an SMF ferrule that may attach to an optical bench, or a silicon optical bench (not shown for diagram clarity).

FIG. 5 illustrates an example flow diagram showing a process 500 for manufacturing an in-package photonics co-packaging assembly on a substrate, in accordance with embodiments.

At block 502, a photonic engine may be coupled to a host IC. In embodiments, the individual actions of block 502 may be indicated by the actions described in relation to FIG. 4D. In embodiments, the host IC may be similar host IC 454, and the photonic engine may be similar to the photonic engine 450. In embodiments, the photonic engine may be similar to the package 100a of FIG. 1A or to package 200a of FIG. 2A. In embodiments, the host IC 454 and the photonic engine 450 may be coupled through an IC package substrate 452. In embodiments, the photonic engine 450 may be coupled to the IC package substrate 452 via solder bumps 450a, and the host IC 454 may be coupled to the IC package substrate 452 via solder bumps 454a .

At block 504, an IHS may be coupled to the photonic engine and the host IC, wherein the IHS is to substantially surround and to thermally couple with the photonic engine and the host IC. In embodiments, the individual actions of block 504 may be indicated by actions described in relation to FIG. 4F. In embodiments, the IHS may be similar to the IHS 456. In embodiments, coupling may include placing a TIM, such as TIM 458, between the IHS 456 and the photonic engine 450 or the host IC 454. In embodiments, thermal energy from the photonic engine 450 and the host IC 454 may conduct upward and into the IHS 456.

At block 506, an optical coupling may be placed through the IHS to provide an optical path external to the IHS for photon signals generated or received by the photonic engine. In embodiments, the individual actions of block 506 may be indicated by actions described in relation to FIG. 4G. In embodiments, the optical coupling may be similar to the optical coupling 462. In embodiments, the optical coupling may pass through the IHS 456 to allow photons to pass between the photonic engine 450 and an SMF array 464.

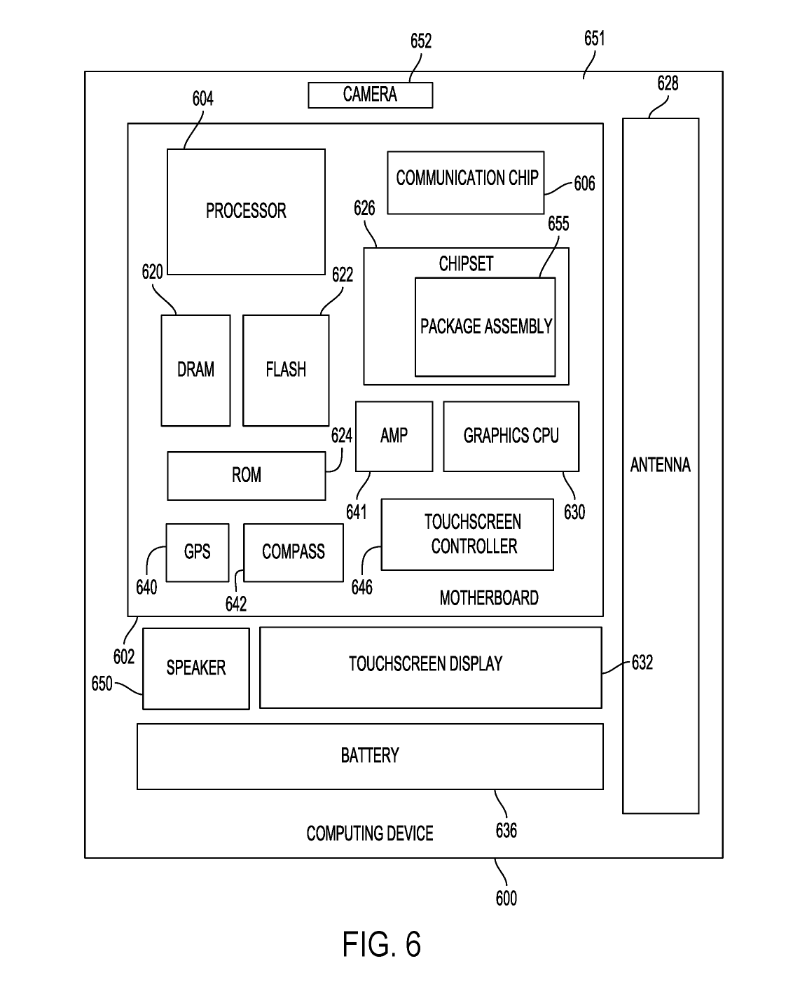

FIG. 6 schematically illustrates a computing device, in accordance with embodiments. Embodiments of the present disclosure may be implemented into a system using any suitable hardware and/or software to configure as desired. FIG. 6 schematically illustrates a computing device 600 in accordance with one embodiment. The computing device 600 may house a board such as motherboard 602 (i.e. housing 651). The motherboard 602 may include a number of components, including but not limited to a processor 604 and at least one communication chip 606. The processor 604 may be physically and electrically coupled to the motherboard 602. In some implementations, the at least one communication chip 606 may also be physically and electrically coupled to the motherboard 602. In embodiments, the at least one communication chip 602 may be or may include a photonic engine 100a of FIG. 1A, or a photonic engine 200a of FIG. 2A. The communication chip 606 may also be or may include an in-package photonics co-packaging assembly similar to the in-package photonics co-packaging assembly 400a of FIG. 4A.

Depending on its applications, computing device 600 may include other components that may or may not be physically and electrically coupled to the motherboard 602. These other components may include, but are not limited to, volatile memory (e.g., DRAM) 620, non-volatile memory (e.g., ROM) 624, flash memory 622, a graphics processor 630, a digital signal processor (not shown), a crypto processor (not shown), a chipset 626, an antenna 628, a display (not shown), a touchscreen display 632, a touchscreen controller 646, a battery 636, an audio codec (not shown), a video codec (not shown), a power amplifier 641, a global positioning system (GPS) device 640, a compass 642, an accelerometer (not shown), a gyroscope (not shown), a speaker 650, a camera 652, and a mass storage device (such as hard disk drive, compact disk (CD), digital versatile disk (DVD), and so forth) (not shown). Further components, not shown in FIG. 6, may include a microphone, a filter, an oscillator, a pressure sensor, or an RFID chip. In embodiments, one or more of the package assembly components 655 may be a package assembly such as package assembly 100a of FIG. 1A, 200a of FIG. 2A, or an in-package photonics co-packaging assembly similar to the in-package photonics co-packaging assembly 400a of FIG. 4A.

The communication chip 606 may enable wireless communications for the transfer of data to and from the computing device 600. The term “wireless” and its derivatives may be used to describe circuits, devices, systems, processes, techniques, communications channels, etc., that may communicate data through the use of modulated electromagnetic radiation through a non-solid medium. The term does not imply that the associated devices do not contain any wires, although in some embodiments they might not. The communication chip 606 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra-mobile broadband (UMB) project (also referred to as “3GPP2”), etc.). IEEE 802.16 compatible BWA networks are generally referred to as WiMAX networks, an acronym that stands for Worldwide Interoperability for Microwave Access, which is a certification mark for products that pass conformity and interoperability tests for the IEEE 802.16 standards. The communication chip 306 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 306 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 306 may operate in accordance with Code Division Multiple Access (CDMA), Time Division Multiple Access (TDMA), Digital Enhanced Cordless Telecommunications (DECT), Evolution-Data Optimized (EV-DO), derivatives thereof, as well as any other wireless protocols that are designated as 3G, 4G, 5G, and beyond. The communication chip 606 may operate in accordance with other wireless protocols in other embodiments.

The computing device 600 may include a plurality of communication chips 606. For instance, a first communication chip 606 may be dedicated to shorter range wireless communications such as Wi-Fi and Bluetooth and a second communication chip 606 may be dedicated to longer range wireless communications such as GPS, EDGE, GPRS, CDMA, WiMAX, LTE, Ev-DO, laser communications, photonics communications and others.

The processor 604 of the computing device 600 may include a die in a package assembly such as, for example, one of package assemblies 100a, 200a, or 400a described herein. The term “processor” may refer to any device or portion of a device that processes electronic data from registers and/or memory to transform that electronic data into other electronic data that may be stored in registers and/or memory.

In various implementations, the computing device 600 may be a laptop, a netbook, a notebook, an UltrabookTM, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, or a digital video recorder. In further implementations, the computing device 600 may be any other electronic device that processes data, for example an all-in-one device such as an all-in-one fax or printing device.

### EXAMPLES

The following paragraphs describe examples of various embodiments:

Example 1 may be a package comprising: photonic (IC) die; a lens coupled to the photonic IC die and disposed at an edge of the package to provide an optical path at the edge of the package for photon signals generated or received by the photonic IC die; and an electronic IC die coupled to the photonic IC die, wherein the electronic IC die is to process electrical signals received from the photonic IC die, and wherein the electronic IC die and the photonic IC die are in a stack formation to facilitate thermal energy conduction from the electronic IC die to the photonic IC die.

Example 2 may include the package of example 1, wherein the lens is substantially at a plane of the electronic IC die.

Example 3 may include the package of example 2, further comprising a prism adjacent to the lens to facilitate photon signal transmission between the lens and the photonic IC.

Example 4 may include the package of example 2, wherein the lens is a ball lens.

Example 5 may include the package of any one of examples 2-4, wherein the photonic IC die and the electronic IC die are coupled by a plurality of bumps.

Example 6 may include the package of example 5, wherein the plurality of bumps are a plurality of micro-bumps.

Example 7 may include the package of example 5, wherein a (RDL) is coupled to the electronic IC die at a side opposite the photonic IC die.

Example 8 may include the package of example 7, wherein the photonic IC die is coupled to the RDL.

Example 9 may include the package of example 8, wherein the photonic IC die is coupled to the RDL with copper (Cu) posts.

Example 10 may include the package of example 5, wherein the electronic IC die further includes one or more TSVs.

Example 11 may include the package of example 1, wherein the lens is substantially within the photonic IC die.

Example 12 may include the package of example 11, wherein the lens is a ball lens.

Example 13 may include the package of any one of examples 11-12, wherein the photonic IC die and the electronic IC die are coupled by a plurality of bumps.

Example 14 may include the package of example 13, wherein the plurality of bumps are a plurality of micro-bumps.

Example 15 may include the package of example 13, wherein a RDL is coupled to the electronic IC die at a side opposite the photonic IC die.

Example 16 may include the package of example 15, wherein the photonic IC die is coupled to the RDL.

Example 17 may include the package of example 16, wherein the photonic IC die is coupled to the RDL with copper (Cu) posts.

Example 18 may include the package of example 13, wherein the electronic IC die further includes one or more TSVs.

Example 19 may be a method for creating a package, comprising: coupling a lens to a photonic IC die, wherein the lens is disposed at an edge of the package to provide an optical path at the edge of the package for photon signals generated or received by the photonic IC die; and coupling an electronic IC die to the photonic IC die in a stack formation, wherein the electronic IC die is to process electrical signals received from the photonic IC die, and wherein the stack formation is to facilitate thermal energy conduction from the electronic IC die to the photonic IC die.

Example 20 may include the method of example 19, wherein coupling the lens to the photonic IC die further includes placing the lens substantially at a plane of the electronic IC die.

Example 21 may include the method of example 20, further comprising coupling a prism adjacent to the lens to facilitate photon signal transmission between the lens and the photonic IC, wherein the prism is adjacent to the lens.

Example 22 may include the method of example 21, wherein the lens is a ball lens.

Example 23 may include the method of any one of examples 20-22, wherein coupling the electronic IC die to the photonic IC die further includes coupling the photonic IC die and the electronic IC die with the plurality of bumps.

Example 24 may include the method of example 23, wherein the plurality of bumps are a plurality of micro-bumps.

Example 25 may include the method of example 23, further comprising coupling a RDL to the electronic IC die at a side opposite the photonic IC die.

Example 26 may include the method of example 25, further comprising coupling the photonic IC die to the RDL.

Example 27 may include the method of example 26, wherein coupling the photonic IC die to the RDL further comprises coupling the photonic IC die to the RDL with copper (Cu) posts.

Example 28 may include the method of example 23, wherein the electronic IC die further includes one or more TSVs.

Example 29 may include the method of example 19, wherein coupling the lens to the photonic IC die further includes placing the lens within the photonic IC die.

Example 30 may include the method of example 29, wherein the lens is a ball lens.

Example 31 may include the method of any one of examples 29-30, wherein coupling the electronic IC die to the photonic IC die further includes coupling the photonic IC die and the electronic IC die with the plurality of bumps.

Example 32 may include the method of example 31, wherein the plurality of bumps are a plurality of micro-bumps.

Example 33 may include the method of example 31, further comprising coupling a RDL to the electronic IC die at a side opposite the photonic IC die.

Example 34 may include the method of example 33, further comprising coupling the photonic IC die to the RDL.

Example 35 may include the method of example 34, wherein coupling the photonic IC die to the RDL further comprises coupling the photonic IC die to the RDL with copper (Cu) posts.

Example 36 may include the method of example 31, wherein the electronic IC die further includes one or more TSVs.

Example 37 may be a co-package assembly, comprising: a photonic engine; a host IC coupled to the photonic engine; an integrated heat spreader (IHS) substantially surrounding and thermally coupled to the photonic engine and the host IC to dissipate heat, wherein the IHS includes an optical coupling to facilitate photon transmission to or photon reception from the photonic engine and a photon source outside the co-package.

Example 38 may include the co-package assembly of example 37, wherein the photonic engine and host IC are coupled with an IC package substrate.

Example 39 may include the co-package assembly of example 37, wherein the optical coupling further comprises a single mode fiber (SMF) array access through an edge of the IHS.

Example 40 may include the co-package assembly of example 37, wherein the IHS thermally coupled to the photonic engine further includes a TIM between the IHS and the photonic engine.

Example 41 may include the co-package assembly of example 37, wherein the IHS thermally coupled to the host IC further includes a TIM between the IHS and the host IC.

Example 42 may be a method for creating a co-package assembly, comprising: coupling a photonic engine to a host IC; coupling an integrated heat spreader (IHS) to the photonic engine and the host IC, wherein the IHS is to substantially surround and to thermally couple with the photonic engine and the IHS; and placing an optical coupling through the IHS, wherein the optical coupling is to provide an optical path external to the IHS for photon signals generated or received by the photonic engine.

Example 43 may include the method of example 42, further comprising placing a TIM between the IHS and the photonic engine or between the IHS and the host IC to facilitate heat dissipation.

Example 44 may include the method of example 42, further comprising coupling the photonic engine and the host IC with an IC package substrate.

Example 45 may include the method of example 42, wherein placing an optical coupling through the IHS further includes placing a single mode fiber (SMF) array access through an edge of the IHS.

Example 46 may include the method of example 42, wherein coupling an integrated heat spreader (IHS) to the photonic engine further includes inserting a TIM between the IHS and the photonic engine.

Example 47 may include the method of example 42, wherein coupling an integrated heat spreader (IHS) to the host IC further includes inserting a TIM between the IHS and the host IC.

Example 48 may be a package comprising: means for coupling a lens to a photoniclC die, wherein the lens is disposed at an edge of the package to provide an optical path at the edge of the package for photon signals generated or received by the photonic IC die; and means for coupling an electronic IC die to the photonic IC die in a stack formation, wherein the electronic IC die is to process electrical signals received from the photonic IC die, and wherein the stack formation is to facilitate thermal energy conduction from the electronic IC die to the photonic IC die.

Example 49 may include the package of example 48, wherein coupling the lens to the photoniclC die further includes means for placing the lens substantially at a plane of the electronic IC die.

Example 50 may include the package of example 49, further comprising means for coupling a prism adjacent to the lens to facilitate photon signal transmission between the lens and the photonic IC, wherein the prism is adjacent to the lens.

Example 51 may include the package of example 50, wherein the lens is a ball lens.

Example 52 may include the package of any one of examples 48-51, wherein coupling the electronic IC die to the photonic IC die further includes means for coupling the photonic IC die and the electronic IC die with the plurality of bumps.

Example 53 may include the package of example 52, wherein the plurality of bumps are a plurality of micro-bumps.

Example 54 may include the package of example 52, further comprising means for coupling a RDL to the electronic IC die at a side opposite the photonic IC die.

Example 55 may include the package of example 54, further comprising means for coupling the photonic IC die to the RDL.

Example 56 may include the package of example 55, wherein coupling the photonic IC die to the RDL further comprises means for coupling the photonic IC die to the RDL with copper (Cu) posts.

Example 57 may include the package of example 52, wherein the electronic IC die further includes one or more TSVs.

Example 58 may include the package of example 48, wherein coupling the lens to the photoniclC die further includes means for placing the lens within the photonic IC die.

Example 59 may include the package of example 58, wherein the lens is a ball lens.

Example 60 may include the package of any one of examples 58-59, wherein coupling the electronic IC die to the photonic IC die further includes means for coupling the photonic IC die and the electronic IC die with the plurality of bumps.

Example 61 may include the package of example 60, wherein the plurality of bumps are a plurality of micro-bumps.

Example 62 may include the package of example 60, further comprising means for coupling a RDL to the electronic IC die at a side opposite the photonic IC die.

Example 63 may include the package of example 62, further comprising means for coupling the photonic IC die to the RDL.

Example 64 may include the package of example 63, wherein coupling the photonic IC die to the RDL further comprises means for coupling the photonic IC die to the RDL with copper (Cu) posts.

Example 65 may include the package of example 60, wherein the electronic IC die further includes one or more TSVs.

Various embodiments may include any suitable combination of the above-described embodiments including alternative (or) embodiments of embodiments that are described in conjunctive form (and) above (e.g., the “and” may be “and/or”). Furthermore, some embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

The above description of illustrated embodiments, including what is described in the Abstract, is not intended to be exhaustive or to limit embodiments to the precise forms disclosed. While specific embodiments are described herein for illustrative purposes, various equivalent modifications are possible within the scope of the embodiments, as those skilled in the relevant art will recognize.

These modifications may be made to the embodiments in light of the above detailed description. The terms used in the following claims should not be construed to limit the embodiments to the specific implementations disclosed in the specification and the claims. Rather, the scope of the invention is to be determined entirely by the following claims, which are to be construed in accordance with established doctrines of claim interpretation.

1-20. (canceled)

21. A co-package assembly, comprising:
a plurality of photonic engines;
a host IC coupled to the plurality of photonic engines;
an integrated heat spreader (IHS) substantially surrounding and thermally coupled to the plurality of photonic engines and the host IC to dissipate heat, wherein the IHS includes a plurality of optical couplings through a side of the IHS to facilitate, respectively, photon transmission to or photon reception from the plurality of photonic engines and a photon source outside the co-package.

22. The co-package assembly of claim 21, wherein the plurality of photonic engines and host IC are coupled with an IC package substrate.

23. The co-package assembly of claim 21, wherein the plurality of optical couplings further comprises a single mode fiber (SMF) array access.

24. The co-package assembly of claim 21, wherein the IHS thermally coupled to the plurality of photonic engines further includes a thermal interface material (TIM) between the IHS and the plurality of photonic engines.

25. The co-package assembly of claim 21, wherein the IHS thermally coupled to the host IC further includes a thermal interface material (TIM) between the IHS and the host IC.

26. The co-package assembly of claim 22, wherein the IHS is thermally coupled to the IC package substrate.

27. A method for creating a co-package assembly, comprising:
coupling a plurality of photonic engines to a host integrated circuit (IC);
coupling an integrated heat spreader (IHS) to the plurality of photonic engines and the host IC, wherein the IHS is to substantially surround and to thermally couple with the plurality of photonic engines and the host IC; and
placing an plurality of optical couplings through the IHS, wherein the plurality of optical couplings are to provide a plurality of optical paths external to the IHS for photon signals generated or received by the photonic engine.

28. The method of claim 27, further comprising placing a thermal interface material (TIM) between the IHS and the plurality of photonic engines or between the IHS and the host IC to facilitate heat dissipation.

29. The method of claim 27, further comprising coupling the plurality of photonic engines and the host IC with an IC package substrate.

30. The method of claim 29, further comprising directly thermally coupling the IHS to the IC package substrate.

31. The method of claim 27, wherein placing a plurality of optical couplings through the IHS further includes placing at least one single mode fiber (SMF) array access through an edge of the IHS.
